(19) United States
(12) Patent Application Publication
(10) Pub. No.: US 2026/0006538 A1
(43) Pub. Date: Jan. 1, 2026

(54) SYSTEMS AND METHODS FOR DETERMINING MOVEMENT OF USER EQUIPMENT DURING COMMUNICATION

(71) Applicant: Samsung Electronics Co., Ltd., Suwon-si (KR)

(72) Inventors: Yangsoo KWON, Suwon-si (KR); Seungjin CHOI, Suwon-si (KR); Yoojin CHOI, Suwon-si (KR); Joohyun DO, Suwon-si (KR); Junho LEE, Suwon-si (KR); Dahae CHONG, Suwon-si (KR)

(73) Assignee: Samsung Electronics Co., Ltd., Suwon-si (KR)

(21) Appl. No.: 19/011,879

(22) Filed: Jan. 7, 2025

(30) Foreign Application Priority Data
Jun. 26, 2024 (KR) 10-2024-0083587

(51) Int. Cl. H04W 48/16; H04B 7/06; H04W 64/00

(52) U.S. Cl. CPC H04W 48/16; H04B 7/06952; H04W 64/006

(57) ABSTRACT

A user equipment (UE) includes a transceiver configured to receive a wireless signal, a communication processor configured to generate a value of at least one indicator based on the wireless signal, and a neural processor configured to receive the value of the at least one indicator from the communication processor and generate a movement determination value by determining whether the UE is moving based on the value of the at least one indicator by using a neural network model, wherein the communication processor is further configured to receive the movement determination value from the neural processor and set an operation mode of the UE based on the movement determination value.

### CROSS-REFERENCE TO RELATED APPLICATION

This application is based on and claims priority under 35 U.S.C. § 119 to Korean Patent Application No. 10-2024-0083587, filed on Jun. 26, 2024, in the Korean Intellectual Property Office, the disclosure of which is incorporated by reference herein in its entirety.

### FIELD

Apparatuses and methods consistent with the present disclosure relate generally to communications, more specifically, methods, systems, and devices for determining occurrence of movement of a user equipment (UE) during communication.

### BACKGROUND

In a wireless communication system, a UE may perform various communication operations to use a wireless network. For example, a UE may periodically perform operations such as cell search and beam sweeping to ensure smooth communication using a wireless network.

Operations periodically performed by a UE for smooth communication result in periodic power consumption in the UE. Accordingly, various methods for reducing power consumption of a UE by minimizing operations periodically performed by the UE are being developed.

### SUMMARY

At least some embodiments of the present disclosure provide a UE capable of minimizing power consumption.

According to some embodiments of the present disclosure, a UE may include a transceiver configured to receive a wireless signal, a communication processor configured to generate a value of at least one indicator based on the wireless signal, and a neural processor configured to receive the value of the at least one indicator from the communication processor and generate a movement determination value by determining whether the UE is moving based on the value of the at least one indicator by using a neural network model. The communication processor may be further configured to receive the movement determination value from the neural processor and set an operation mode of the UE based on the movement determination value.

According to some embodiments of the present disclosure, a UE may include a transceiver configured to receive a wireless signal, and a communication processor configured to generate a value of at least one indicator based on the wireless signal. The communication processor may be further configured to generate a movement determination value by determining whether the UE is moving based on the value of the at least one indicator, by using a neural network model, and set an operation mode of the UE based on the movement determination value.

According to some embodiments of the present disclosure, a UE may include a transceiver configured to receive a wireless signal, a communication processor configured to generate a value of at least one indicator based on the wireless signal, an application processor configured to generate at least one sensing value using at least one sensor, and a neural processor configured to receive the value of the at least one indicator from the communication processor, receive the at least one sensing value from the application processor, and generate a movement determination value by determining whether the UE is moving based on the value of the at least one indicator and the at least one sensing value.

### BRIEF DESCRIPTION OF THE DRAWINGS

Embodiments will be more clearly understood from the following detailed description taken in conjunction with the accompanying drawings in which:

FIG. 1 is a schematic diagram illustrating a wireless communication system, consistent with some embodiments of the present disclosure.

FIG. 2 is a block diagram illustrating an example of a UE, consistent with some embodiments of the present disclosure.

FIG. 3 is a schematic diagram illustrating a structure of a neural network model, consistent with some embodiments of the present disclosure.

FIGS. 4A to 4C are schematic diagrams illustrating embodiments in which a neural processor generates a movement determination value by using a plurality of neural network models, consistent with some embodiments of the present disclosure.

FIG. 5 is a block diagram illustrating an example of a UE, consistent with some embodiments of the present disclosure.

FIG. 6 is a flowchart illustrating a method for operating a UE, consistent with some embodiments of the present disclosure.

FIG. 7 is a flowchart illustrating a method for setting an operation mode of a UE, consistent with some embodiments of the present disclosure.

FIG. 8 is a flowchart illustrating a method for operating a UE, consistent with some embodiments of the present disclosure.

FIGS. 9A and 9B are flowcharts illustrating an operation according to an operation mode of a UE, consistent with some embodiments of the present disclosure.

FIG. 10 is a block diagram illustrating a UE, consistent with some embodiments of the present disclosure.

### DETAILED DESCRIPTION OF THE EMBODIMENTS

Embodiments will be described in detail with reference to the accompanying drawings.

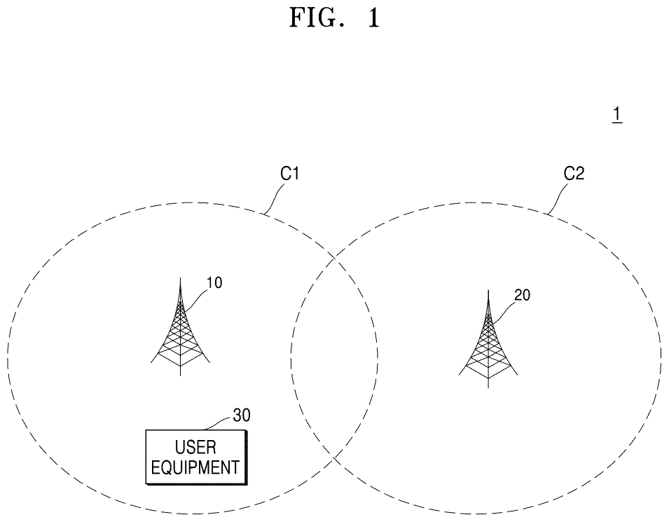

FIG. 1 is a schematic diagram illustrating a wireless communication system, consistent with some embodiments of the present disclosure.

Referring to FIG. 1, a wireless communication system 1 may include a base station (e.g., 10 or 20) and a UE 30.

The wireless communication system 1 may provide a communication service based on at least one of a plurality of wireless networks to the UE 30. For example, the wireless communication system 1 may provide a communication service based on at least one of a 3^{rd} generation (3G) network, a 4th generation (4G) network, a wireless broadband (Wibro) network, a global system for mobile communication (GSM) network, a 5th generation (5G) network, and a 6th generation (6G) network.

Various functions described below may be implemented or supported by artificial intelligence technology or one or more computer programs, each of which includes computer-readable program code and is implemented in a computer-readable medium. The terms “application” and “program” refer to one or more computer programs, software components, sets of instructions, procedures, functions, objects, classes, instances, associated data, or portions thereof suitable for implementation of suitable computer-readable program code. The term “computer-readable program code” includes any type of computer code, including source code, object code, and executable code. The term “computer-readable medium” includes any type of medium capable of being accessed by a computer, such as a read-only memory (ROM), a random-access memory (RAM), a hard disk drive, a compact disc (CD), a digital video disc (DVD), or any other type of memory. “Non-transitory” computer-readable media exclude wired, wireless, optical, or other communication links that transmit transitory electrical or other signals. The non-transitory computer-readable media include media in which data may be permanently stored, and media in which data may be stored and later overwritten, such as a rewritable optical disk or a removable memory device.

In some embodiments described below, a hardware approach is described as an example. However, because the embodiments may include technology using both hardware and software, the embodiments do not exclude a software-based approach.

The base station (e.g., 10 or 20) may generally refer to a fixed station communicating with the UE 30, and may exchange control information and data by communicating with the UE 30. For example, the base station may be referred to in various ways as a Node B, an evolved-Node B (eNB), a next generation Node B (gNB), a sector, a site, a base transceiver system (BTS), an access point (AP), a relay node, a remote radio head (RRH), a radio unit (RU), a small cell, a wireless device, or a device.

Although FIG. 1 only shows two base stations in the wireless communication system 1, that is, the first base station 10 and the second base station 20, the scope of the present disclosure is not so limited. In some embodiments, the wireless communication system 1 may include one base station, or three or more base stations.

The UE 30 may be fixed or mobile. The UE 30 may take any form of devices that transmit and receive data and/or control information by communicating with a base station (e.g., 10). For example, the UE 30 may be a terminal, a terminal equipment, a mobile station (MS), a mobile terminal (MT), a user terminal (UT), a subscriber station (SS), a wireless communication device, a wireless device, a device, or a handheld device.

Although FIG. 1 shows only one UE 30 in the wireless communication system 1, the scope of the present disclosure is not so limited. In some embodiments, the wireless communication system 1 may include two or more UEs.

The base station (e.g., 10 or 20) may be connected to the UE 30 within a coverage (C1 or C2) and may provide a communication service to the UE 30 based on a wireless network. In the embodiment of FIG. 1, the first base station 10 may be connected to the UE 30 within the first coverage C1. In some embodiments, although not shown in FIG. 1, the UE 30 may be located within the second coverage C2 and connected to the second base station 20.

The UE 30 may move within the first coverage C1. When the UE 30 moves within the first coverage C1, the UE 30 may perform a beam sweeping operation to communicate with the first base station 10 by using an appropriate beam according to a position change. In this case, the UE 30 may periodically perform a beam sweeping operation, and thus, even when a location of the UE 30 changes, the UE 30 may always perform communication by using an appropriate beam. However, when a beam sweeping operation is periodically performed, continuous power consumption may occur during a process of performing the beam sweeping operation.

Also, the UE 30 may move from the first coverage C1 to the second coverage C2. As such, when the UE 30 moves from the first coverage C1 to the second coverage C2, the UE 30 may perform a cell search operation to perform smooth communication using the wireless communication system 1. In this case, the UE 30 may periodically perform a cell search operation, and thus, even when the UE 30 moves into another coverage, the UE 30 may always perform communication using the wireless communication system 1. However, when a cell search operation is periodically performed, continuous power consumption may occur during a process of performing the cell search operation.

In an embodiment, the UE 30 may determine whether the UE 30 is moving based on a wireless signal and a sensor, and may determine whether to periodically perform a cell search operation and a beam sweeping operation based on whether the UE 30 is moving. As such, because whether to periodically perform a cell search operation and a beam sweeping operation is determined based on whether the UE 30 is moving, power consumption of the UE 30 may be reduced.

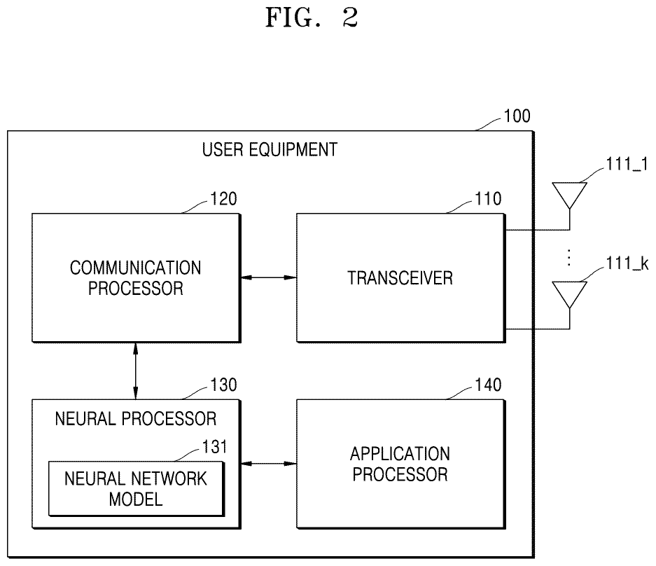

FIG. 2 is a block diagram illustrating an example of a UE, consistent with some embodiments of the present disclosure.

Referring to FIG. 2, a UE 100 according to an embodiment may include a transceiver 110, a plurality of antennas 111_1 to 111_k, a communication processor 120, and a neural processor 130. The UE 100 may also include an application processor 140. Also, although not shown in FIG. 2, the UE 100 may include some other elements necessary for an operation of the UE 100, such as a memory and an interface.

The transceiver 110 may receive a wireless signal transmitted by a base station using the plurality of antennas 111_1 to 111_k. The transceiver 110 may down-convert the received wireless signal to generate an intermediate frequency signal or a baseband signal. The transceiver 110 may transmit the converted wireless signal to the communication processor 120.

The communication processor 120 may control an overall operation related to communication of the UE 100. The communication processor 120 may be a processor having a structure suitable to perform an operation related to communication.

The communication processor 120 may obtain data by performing a processing operation of filtering, decoding, and/or digitizing the wireless signal received from the transceiver 110, and may generate data for communication with the base station based on the obtained data.

The communication processor 120 may encode, multiplex, and/or analogize the generated data and may provide the signal as a wireless signal to the transceiver 110. The transceiver 110 may perform frequency up-conversion on the wireless signal and may transmit a result to the base station using the antennas 111_1 to 111_k.

In an embodiment, the communication processor 120 may generate a value of at least one indicator based on the wireless signal. The at least one indicator may be an indicator indicating information related to communication between the base station and the UE 100 which may be obtained using the wireless signal. The at least one indicator may include indicators suitable to determine whether the UE 30 is moving.

For example, the at least one indicator may include at least one of: a global cell ID, a physical cell ID, a frequency band, a bandwidth, received signal received power (RSRP), reference signal received quality (RSRQ), a received signal strength indicator (RSSI), a signal to interference plus noise ratio (SINR), a number of resource blocks, a channel quality indicator (CQI), a rank indicator (RI), a precoding matrix indicator (PMI), a modulation and coding scheme (MCS), a modulation order, a block error rate (BLER), transmission power, a Doppler frequency, or a delay spread.

Hereinafter, when the value of the at least one indicator is generated based on the wireless signal, it may indicate that the value of the at least one indicator is generated based on the baseband signal generated using the frequency down-conversion on the wireless signal.

The communication processor 120 may transmit the generated value of the at least one indicator to the neural processor 130. The communication processor 120 may receive a movement determination value generated by the neural processor 130 based on the value of the least one indicator. The movement determination value may be a value indicating whether the UE 100 is moving, and may be generated by the neural processor 130 as described below.

In an embodiment, the communication processor 120 may set an operation mode of the UE 100 based on the movement determination value received from the neural processor 130.

In an embodiment, when the movement determination value indicates that the UE 100 is moving, the communication processor 120 may set the operation mode of the UE 100 to a first operation mode. The first operation mode may be a mode in which operations periodically performed by the UE 100 to perform smooth communication are performed as they are. When the UE 100 is moving, it may indicate that a change occurs in a communication environment between the UE 100 and the base station, and thus, the UE 100 may perform operations periodically performed to perform smooth communication as they are in the first operation mode.

For example, when the operation mode is the first operation mode, the UE 100 may periodically perform a cell search operation. Also, when the operation mode is the first operation mode, the UE 100 may periodically perform a beam sweeping operation.

In an embodiment, when the movement determination value indicates that the UE 100 is not moving, the communication processor 120 may set the operation mode of the UE 100 to a second operation mode. The second operation mode may be a mode in which operations periodically performed by the UE 100 to perform smooth communication are not performed. When the UE 100 is not moving, it may indicate that a change does not occur in a communication environment between the UE 100 and the base station, and thus, the UE 100 may not perform operations periodically performed to perform smooth communication in the second operation mode.

For example, when the operation mode is the second operation mode, the UE 100 may maintain a preset cell without periodically performing a cell search operation. Also, when the operation mode is the second operation mode, the UE 100 may maintain a preset beam without periodically performing a beam sweeping operation.

The neural processor 130 may include a processor for implementing control and arithmetic logic required to execute a neural network and/or machine learning algorithm. The neural processor 130 may be a processor having a structure suitable to perform an operation related to a neural network and/or machine learning algorithm. For example, the neural processor may include an artificial intelligence (AI) accelerator and/or a neural processing unit (NPU).

In an embodiment, the neural processor 130 may receive the value of the at least one indicator from the communication processor 120. The neural processor 130 may generate a movement determination value by determining whether the UE 100 is moving based on the value of the at least one indicator, by using a neural network model 131.

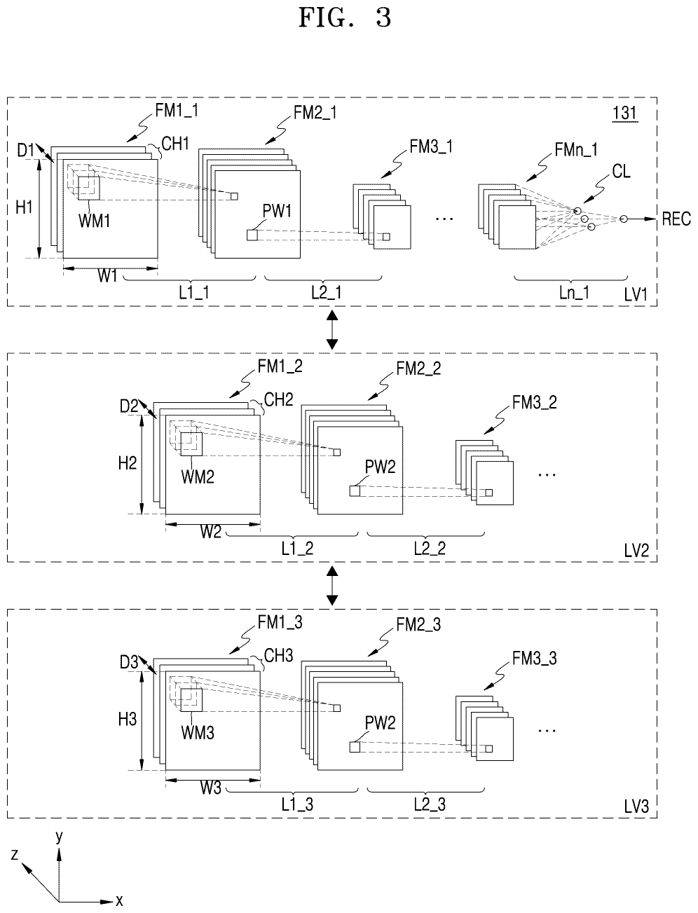

The neural network model 131 may be a model configured to generate output data by performing a large amount of operations on input data. Any neural network structure from among a multi-layer perceptron (MLP) structure, a convolutional neural network (CNN) structure, a region with convolution neural network (R-CNN) structure, a region proposal network (RPN) structure, a recurrent neural network (RNN) structure, a stacking-based deep neural network (S-DNN) structure, a state-space dynamic neural network (S-SDNN) structure, a deconvolution network structure, a deep belief network (DBN) structure, a restricted Boltzmann machine (RBM) structure, a fully convolution network structure, a classification network structure, a plain residual network structure, a dense network structure, a hierarchical pyramid network structure, a transformer structure, and a long short-term memory (LSTM) structure may be applied to the neural network model 131. An example of the neural network model 31 may be as shown in FIG. 3 described below.

In an embodiment, the neural network model 131 may receive the value of the at least one indicator as input data, may determine whether the UE 100 is moving by performing a large amount operations on the value of the at least one indicator, and may generate a movement determination value indicating whether the UE 100 is moving as output data.

The value of the at least one indicator input to the neural network model 131 may be preprocessed so that it can be easily processed by the neural network model 131. Also, a difference between a value of an indicator generated at a first time and a value of an indicator generated at a second time may be additionally input to the neural network model 131.

The neural network model 131 may be trained to determine whether the UE 100 is moving based on previously collected data. Also, the neural network model 131 may be trained to determine whether the UE 100 is moving based on data received in real time from the communication processor 120.

The neural processor 130 may selectively use some of the at least one indicator to determine whether the UE 100 is moving. For example, the neural processor 130 may determine whether the UE 100 is moving based on values of indicators related to reception intensities of wireless signals. However, this is merely an example, and in some embodiments, the UE 100 may use all of many indicators or may intensively use some of many indicators to determine whether the UE 100 is moving.

The movement determination value may be a value indicating whether the UE 100 is moving. In an embodiment, the movement determination value may be a value probabilistically indicating whether the UE 100 is moving. For example, when the movement determination value is 0.8, it may indicate a probability that the UE 100 is moving is 80%.

The application processor 140 may control an overall operation of the UE 100.

In an embodiment, the application processor 140 may generate at least one sensing value using at least one sensor. The at least one sensor may sense various values according to a change in an external environment of the UE 100. For example, the at least one sensor may include at least one of: a gyro sensor, an acceleration sensor, a linear acceleration sensor, or a geomagnetic sensor.

The at least one sensor may be included in the application processor 140 or may be separately implemented outside the application processor 140. The at least one sensor may generate a sensing value, and the application processor 140 may transmit the at least one sensing value generated using the at least one sensor to the neural processor 130.

In an embodiment, the neural processor 130 may receive the at least one sensing value from the application processor 140. The neural processor 130 may generate a movement determination value by determining whether the UE 100 is moving based on the value of the at least one indicator and the at least one sensing value, by using the neural network model 131.

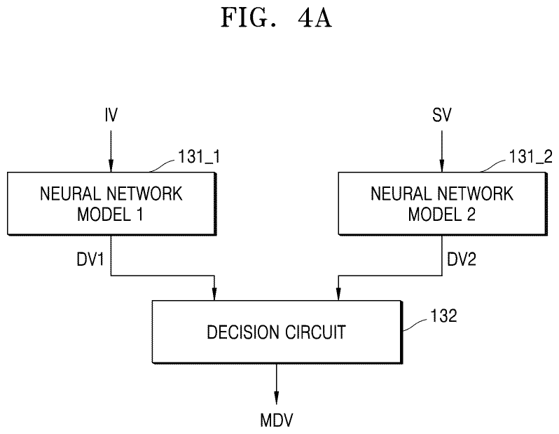

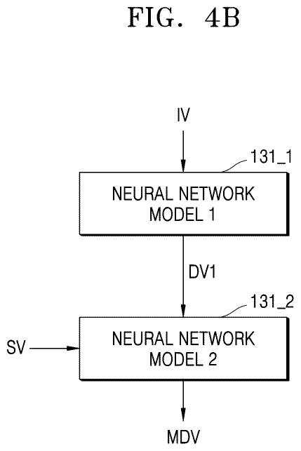

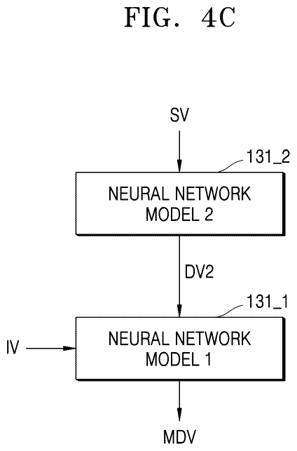

Upon determination of whether the UE 100 is moving based on the value of the at least one indicator and the at least one sensing value, the neural processor 130 may determine whether the UE 100 is moving by using a plurality of neural network models, instead of one neural network model 131. An embodiment in which the neural processor 130 uses a plurality of neural network models will be described below with reference to FIGS. 4A to 4C.

In an embodiment, when the neural processor 130 uses one neural network model 131, the neural network model 131 may receive the value of the at least one indicator and the at least one sensing value as input data, may determine whether the UE 100 is moving by performing a large amount of operations on the value of the at least one indicator and the at least one sensing value, and may generate a movement determination value indicating whether the UE 100 is moving as output data.

The neural processor 130 may selectively use some of the at least one indicator and some of the at least one sensing value to determine whether the UE 100 is moving. For example, the neural processor 130 may determine whether the UE 100 is moving based on values of indicators related to reception intensities of wireless signals and a sensing value of detecting an acceleration of the UE 100. However, this is merely an example, and in some embodiments, the UE 100 may use all of many indicators or may intensively use some of many indicators to determine whether the UE 100 is moving.

The UE 100 according to an embodiment as described above may generate a value of at least one indicator based on a wireless signal, may generate a movement determination value of the UE 100 based on the value of the at least one indicator, and may set an operation mode of the UE 100 based on the movement determination value. Accordingly, power consumption of the UE 100 may be reduced. Also, the UE 100 may generate a movement determination value of the UE 100 by using at least one sensing value along with the value of the at least one indicator, and may set an operation mode of the UE 100 based on the movement determination value, thereby reducing power consumption of the UE 100.

FIG. 3 is a schematic diagram illustrating a structure of a neural network model described with respect to FIG. 2.

Referring to FIG. 3, an example of the neural network model 131 is illustrated. The neural network model 131 may be used to determine whether the UE 100 is moving, and the neural network model 131 may be effectively trained to determine whether the UE 100 is moving based on a structure described below.

The neural network model 131 may include a plurality of levels (e.g., LV1 to LV3). However, the scope of the present disclosure is not so limited. In some embodiments, the neural network model 131 may include only one level or two or more levels. Hereinafter, although a first level LV1 is described, the description may apply to other levels included in the neural network model 131. Also, some of layers at the first level LV1 may be omitted or layers other than those described at the first level LV1 may be added to the neural network model 131 when necessary.

In this case, in an embodiment, a value of at least one indicator and at least one sensing value input to the neural network model 131 may be input to the first level LV1, or may be processed through filtering and may be input to a second level LV2.

The first level LV1 may include a plurality of layers (e.g., L1_1 to Ln_1). The neural network model 131 having such a multi-layer structure may be referred to as a deep neural network (DNN) or a deep learning architecture. Each of the plurality of layers (e.g., L1_1 to Ln_1) may be a linear layer or a non-linear layer, and in some embodiments, at least one layer and at least one non-linear layer may be combined and referred to as one layer. For example, a linear layer may include a convolution layer and a fully-connected layer, and a non-linear layer may include a pooling layer and an activation layer.

For example, the first layer L1_1 may be a convolution layer, the second layer L2_1 may be a pooling layer, and an n^{th} layer Ln_1 that is an output layer may be a fully-connected layer. The neural network model 131 may further include an activation layer, and may further include a layer that performs another type of operation.

Each of the plurality of layers (e.g., L1_1 to Ln_1) may receive input data or a feature map generated in a previous layer as an input feature map, and may generate an output feature map by performing an operation on the input feature map. In this case, the term “feature map” refers to data in which various features of input data are expressed. Feature maps (e.g., FM1_1 to FMn_1) may have a two-dimensional matrix structure or three-dimensional matrix (or a tensor) structure including a plurality of feature values. Each of the feature maps (e.g., FM1_1 to FMn_1) may have a width W1 (or a column), a height H1 (or a row), and a depth D1, and the width W1, the height H1, and the depth D1 may respectively correspond to an x-axis, a y-axis, and a z-axis in a coordinate system. In this case, the depth D1 may be referred to as a channel number CH1. Although three channels (e.g., CH1, CH2, and CH3) are illustrated in FIG. 3, the inventive concept is not limited thereto, and the neural network model 131 may include one channel or two or more channels.

The first layer L1_1 may convolute a first feature map FM1_1 with a weight map WM1 to generate a second feature map FM2_1. The weight map WM1 may have a 2D or 3D matrix structure including a plurality of weight values. The weight map WM1 may be referred to as a kernel. The weight map WM1 may filter the first feature map FM1_1, and may be referred to as a filter or a kernel. Channels of the weight map WM1 may be convoluted with corresponding channels of the first feature map FM1_1. The weight map WM1 is shifted to traverse the first feature map FM1_1 as a sliding window. During each shift, each of weights included in the weight map WM1 may be multiplied by and added to all feature values in a region overlapping the first feature map FM1_1. As the first feature map FM1_1 and the weight map WM1 are convoluted, one channel of the second feature map FM2_1 may be generated. Although one weight map WM1 is illustrated in FIG. 3, in some embodiments, a plurality of weight maps may be convoluted with the first feature map FM1_1 to generate a plurality of channels of the second feature map FM2_1. In other words, the number of channels of the second feature map FM2_1 may correspond to the number of weight maps.

The second layer L2_1 may generate a third feature map FM3_1 by changing a spatial size of the second feature map FM2_1 through pooling. The pooling may be referred to as sampling or down-sampling. A 2D pooling window PW1 may be shifted on the second feature map FM2_1 in units of the size of the pooling window PW1, and a maximum value of feature values (or an average value of feature values) of a region overlapping the pooling window PW1 may be selected. Accordingly, the third feature map FM3_1 with a changed spatial size may be generated from the second feature map FM2_1. The number of channels of the third feature map FM3_1 and the number of channels of the second feature map FM2_1 may be the same. The n^{th} layer Ln_1 may classify a class CL of input data by combining features of the n^{th} feature map FMn_1. Also, the n^{th} layer may generate a recognition signal REC corresponding to the class CL. The n^{th} layer Ln_1 may be omitted if necessary.

The neural network model 131 may include one level or a plurality of levels. Each of the plurality of levels may receive a feature map generated from data input at each level as an input feature map and may generate an output feature map or a recognition signal REC by performing an operation on the input feature map. For example, the first level LV1 may receive a feature map generated from input data as an input feature map. The first layer L1_1 may receive the first feature map FM1_1 generated from the input data. The second level LV2 may receive a feature map generated from first reconstruction data as an input feature map. A first layer L1_2 may receive a first feature map FM1_2 generated from the first reconstruction data. The third level LV3 may receive a feature map generated from second reconstruction data as an input feature map. The first layer L1_3 may receive a first feature map FM1_3 generated from the second reconstruction data. Units of the first reconstruction data and the second reconstruction data may be different from each other. Widths W1, W2, and W3, heights H1, H2, and H3, and depths D1, D2, and D3 of the first feature map FM1_1, the first feature map FM1_2, and the first feature map FM1_3 may be different from each other.

The plurality of levels may be organically connected to each other. In an embodiment, feature maps output from a layer included in each of the plurality of levels may be organically connected to feature maps of other levels. For example, the neural network model 131 may perform an operation for extracting features of the third feature map 3_1 and the first feature map FM1_2 to generate a new feature map. In an embodiment, the n^{th} layer Ln_1 may exist only at one layer, and may classify the class CL of input data by combining features of a feature map of each level.

In an embodiment, a configuration including the number and combination of feature maps and layers of the neural network model 131 may be determined to effectively determine whether the UE 100 is moving.

FIGS. 4A to 4C are diagrams illustrating embodiments in which a neural processor generates a movement determination value by using a plurality of neural network models, according to an embodiment.

Referring to FIG. 4A, an embodiment of generating a movement determination value MDV by using a first neural network model 131_1, a second neural network model 131_2, and a decision circuit 132 is illustrated.

In the embodiment of FIG. 4A, the first neural network model 131_1 may generate a first determination value DV1 by determining whether the UE 100 is moving based on a value IV of at least one indicator. That is, the first neural network model 131_1 may receive the value IV of the at least one indicator as input data, may determine whether the UE 100 is moving by performing a large amount of operations on the value IV of the at least one indicator, and may generate the first determination value DV1 indicating whether the UE 100 is moving as output data.

In the embodiment of FIG. 4A, the first determination value DV1 may be a value probabilistically indicating whether the UE 100 is moving determined based on the value IV of the at least one indicator. For example, when the first determination value DV1 is 0.7, it may indicate that a probability of the UE 100's movement determined based on the value IV of the at least one indicator is 70%.

The neural processor 130 may generate the first determination value DV1 by determining whether the UE 100 is moving based on the value IV of the at least one indicator, by using the first neural network model 131_1.

In the embodiment of FIG. 4A, the second neural network model 131_2 may generate a second determination value DV2 by determining whether the UE 100 is moving based on at least one sensing value SV. That is, the second neural network model 131_2 may receive the at least one sensing value SV as input data, may determine whether the UE 100 is moving by performing a large amount of operations on the at least one sensing value SV, and may generate the second determination value DV2 indicating whether the UE 100 is moving as output data.

In the embodiment of FIG. 4A, the second determination value DV2 may be a value probabilically indicating whether the UE 100 is moving determined based on the at least one sensing value SV. For example, when the second determination value DV2 is 0.9, it may indicate that a probability of the UE 100's movement determined based on the at least one sensing value SV is 90%.

The neural processor 130 may generate the second determination value DV2 by determining whether the UE 100 is moving based on the at least one sensing value SV, by using the second neural network model 131_2.

In the embodiment of FIG. 4A, the decision circuit 132 may generate the movement determination value MDV based on the first determination value DV1 and the second determination value DV2.

In an embodiment, the decision circuit 132 may generate the movement determination value MDV based on a higher value from among the first determination value DV1 and the second determination value DV2. For example, when the first determination value DV1 is 0.4 and the second determination value DV2 is 0.8, the decision circuit 132 may determine that the movement determination value MDV is 0.8.

In another example, the decision circuit 132 may generate the movement determination value MDV based on an average value of the first determination value DV1 and the second determination value DV2. For example, when the first determination value DV1 is 0.5 and the second determination value DV2 is 0.9, the decision circuit 132 may determine that the movement determination value MDV is 0.7.

The neural processor 130 may generate the movement determination value MDV based on the first determination value DV1 and the second determination value DV2, using the decision circuit 132.

Next, referring to FIG. 4B, an embodiment of generating the movement determination value MDV by using the first neural network model 131_1 and the second neural network model 131_2 is illustrated.

In the embodiment of FIG. 4B, the first neural network model 131_1 may generate the first determination value DV1 by determining whether the UE 100 is moving based on the value IV of the at least one indicator. The first neural network model 131_1 of the embodiment of FIG. 4B may perform substantially the same operation as the first neural network model 131_1 of the embodiment of FIG. 4A.

In the embodiment of FIG. 4B, the second neural network model 131_2 may generate the movement determination value MDV by determining whether the UE 100 is moving based on the first determination value DV1 and the at least one sensing value SV. That is, the second neural network model 131_2 may receive the first determination value DV1 and the at least one sensing value SV as input data, may determine whether the UE 100 is moving by performing a large amount of operations on the first determination value DV1 and the at least one sensing value SV, and may generate the movement determination value MDV indicating whether the UE 100 is moving as output data.

The neural processor 130 may generate the movement determination value MDV by determining whether the UE 100 is moving based on the first determination value DV1 and the at least one sensing value SV, by using the second neural network model 131_2.

Last, referring to FIG. 4C, an embodiment of generating the movement determination value MDV by using the second neural network model 131_2 and the first neural network model 131_1 is illustrated.

In the embodiment of FIG. 4C, the second neural network model 131_2 may generate the second determination value DV2 by determining whether the UE 100 is moving based on the at least one sensing value SV. The second neural network model 131_2 of the embodiment of FIG. 4C may perform substantially the same operation as the second neural network model 131_2 of the embodiment of FIG. 4A.

In the embodiment of FIG. 4C, the first neural network model 131_1 may generate the movement determination value MDV by determining whether the UE 100 is moving based on the second determination value DV2 and the value IV of the at least one indicator. That is, the first neural network model 131_1 may receive the second determination value DV2 and the value IV of the at least one indicator as input data, may determine whether the UE 100 is moving by performing a large amount of operations on the second determination value DV2 and the value IV of the at least one indicator, and may generate the movement determination value MDV indicating whether the UE 100 is moving as output data.

The neural processor 130 may generate the movement determination value MDV by determining whether the UE 100 is moving based on the second determination value DV2 and the value IV of the at least one indicator, by using the first neural network model 131_1.

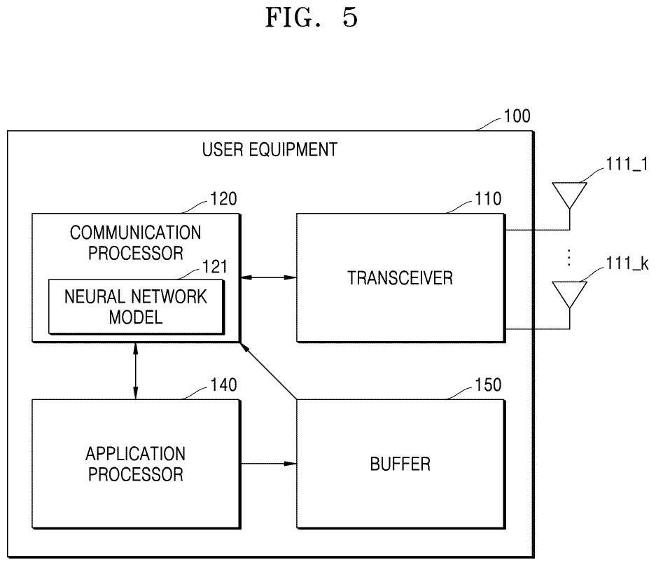

FIG. 5 is a block diagram illustrating another example of a UE, according to an embodiment.

Referring to FIG. 5, the UE 100 according to an embodiment may include a transceiver 110, a plurality of antennas 111_1 to 111_k, and a communication processor 120. The UE 100 may also include an application processor 140 and a buffer 150. Also, although not shown in FIG. 5, the UE 100 may include other elements necessary for an operation of the UE 100, such as a memory and/or an interface.

The transceiver 110 and the plurality of antennas 111_1 to 111_k of the embodiment of FIG. 5 may perform substantially the same operation as the transceiver 110 and the plurality of antennas 111_1 to 111_k of the embodiment of FIG. 2.

The communication processor 120 of the embodiment of FIG. 5 may use a neural network model 121, unlike the communication processor 120 of the embodiment of FIG. 2.

In the embodiment of FIG. 5, the communication processor 120 may generate a value of at least one indicator based on a wireless signal. The communication processor 120 may generate a movement determination value by determining whether the UE 100 is moving based on the value of the at least one indicator by using the neural network model 121. The communication processor 120 may input the value of the at least one indicator to the neural network model 121 as input data, and may receive a movement determination value generated based on the value of the at least one indicator as output data using the neural network model 121.

The communication processor 120 may set an operation mode of the UE 100 based on a movement determination value received from the neural network model 121.

An operation of the neural network model 121 of the embodiment of FIG. 5 may be the same as an operation of the neural network model 131 of the embodiment of FIG. 2.

The application processor 140 of the embodiment of FIG. 5 may perform an operation similar to that of the application processor 140 of the embodiment of FIG. 2.

In the embodiment of FIG. 5, the application processor 140 may generate at least one sensing value using at least one sensor. The application processor 140 may transmit the at least one sensing value generated using the at least one sensor to the communication processor 120. In this case, the application processor 140 may directly input the at least one sensing value to the neural network model 121 in the communication processor 120.

In the embodiment of FIG. 5, the UE 100 may further include the buffer 150. The buffer 150 may receive and temporarily store the at least one sensing value from the application processor 140. In this case, the communication processor 120 may receive the at least one sensing value from the buffer 150.

In the embodiment of FIG. 5, the communication processor 120 may generate a movement determination value by determining whether the UE 100 is moving based on the value of the at least one indicator and the at least one sensing value by using the neural network model 121. The communication processor 120 may input the value of the at least one indicator and the at least one sensing value to the neural network model 121 as input data, and may receive a movement determination value generated based on the value of the at least one indicator and the at least one sensing value as output data using the neural network model 121.

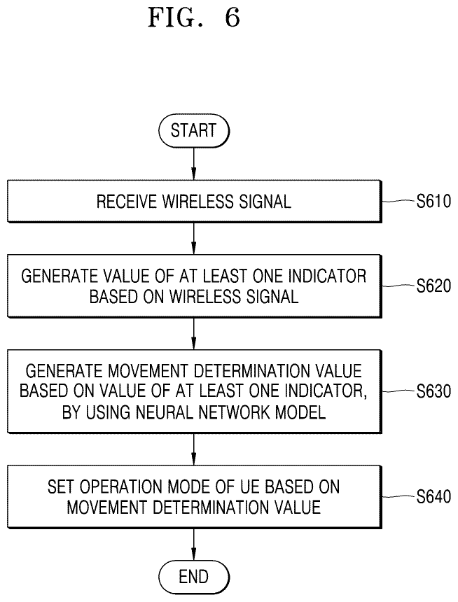

FIG. 6 is a flowchart illustrating an example of an operating method of a UE, according to an embodiment.

Referring to FIG. 6, an embodiment, a UE, such as the UE 100 described above with respect to FIG. 2 or FIG. 5, generates a movement determination value based on a value of at least one indicator and generates an operation mode of the UE.

In operation S610, the UE may receive a wireless signal. For example, a transceiver of the UE may receive a wireless signal transmitted by a base station using the plurality of antennas.

In operation S620, the UE may generate a value of at least one indicator based on the wireless signal. The UE may generate the value of the at least one indicator which is used to determine whether the UE is moving. The UE may generate the value of the at least one indicator based on a wireless signal using a communication processor.

In operation S630, the UE may generate a movement determination value based on the value of the at least one indicator.

In some embodiments, as in the embodiment of FIG. 2, when a neural network model is used by a neural processor, the communication processor may transmit the value of the at least one indicator to the neural processor. Next, the neural processor may generate a movement determination value based on the value of the at least one indicator by using a neural network model. Next, the neural processor may transmit the movement determination value to the communication processor.

In some embodiments, as in the embodiment of FIG. 5, when the neural network model is used by the communication processor, the communication processor may generate a movement determination value based on the value of the at least one indicator by using the neural network model.

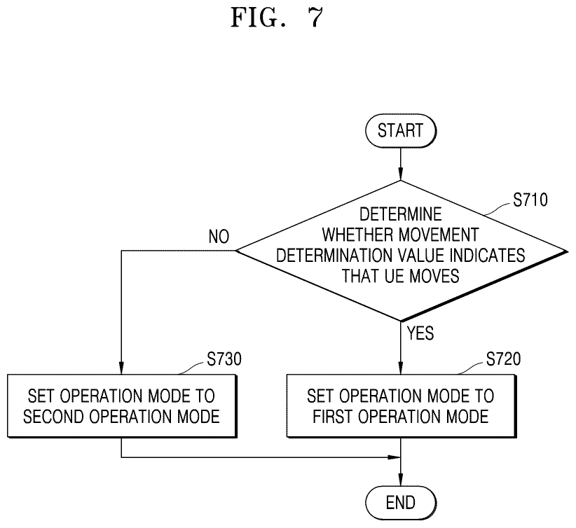

In operation S640, the UE may set an operation mode of the UE based on the movement determination value. Operation S640 will be described below in more detail with reference to FIG. 7.

When the operating method of the UE according to an embodiment as described above is used, a value of at least one indicator may be generated based on a wireless signal, a movement determination value of the UE may be generated based on the value of the at least one indicator, and an operation mode of the UE may be set based on the movement determination value. Accordingly, power consumption of the UE may be reduced.

FIG. 7 is a flowchart illustrating a method for setting an operation mode of a UE, according to an embodiment.

Referring to FIG. 7, in operation S710, a UE, such as the UE 100 described above with respect to FIG. 2 or FIG. 5, may determine, using the communication processor 120, whether a movement determination value indicates that the UE is moving.

In an embodiment, assuming that the movement determination value probabilistically indicates whether the UE is moving, when the movement determination value is greater than or equal to 0.5, the communication processor may determine that the movement determination value indicates that the UE is moving. In contrast, when the movement determination value is less than 0.5, the communication processor may determine that the movement determination value indicates that the UE does not move.

When it is determined that the movement determination value indicates that the UE is moving, the method proceeds to operation S720. In operation S720, the UE may set an operation mode of the UE to a first operation mode using the communication processor.

In contrast, when it is determined that the movement determination value indicates that the UE does not move, the method proceeds to operation S730. In operation S730, the UE may set an operation mode of the UE to a second operation mode using the communication processor.

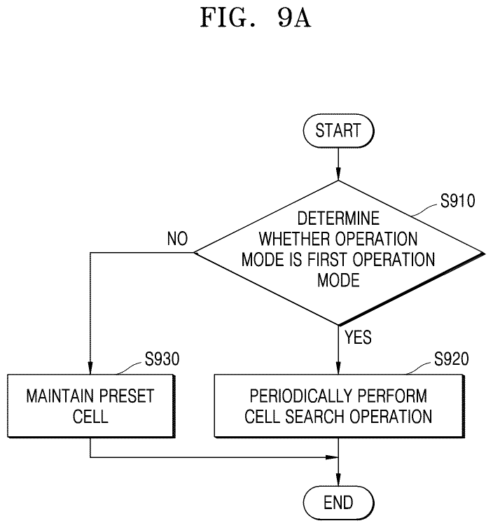

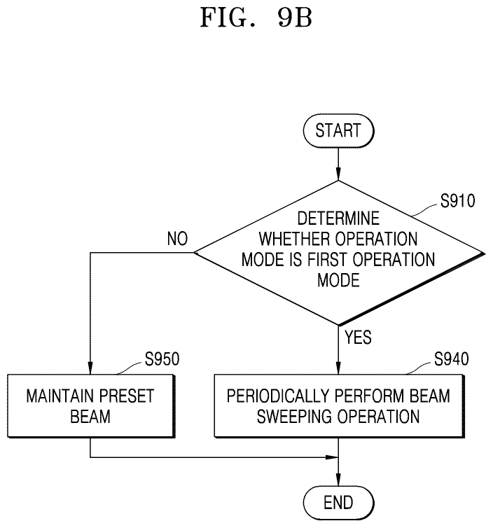

An operation of the UE according to an operation mode of the UE will be described below with reference to FIG. 9.

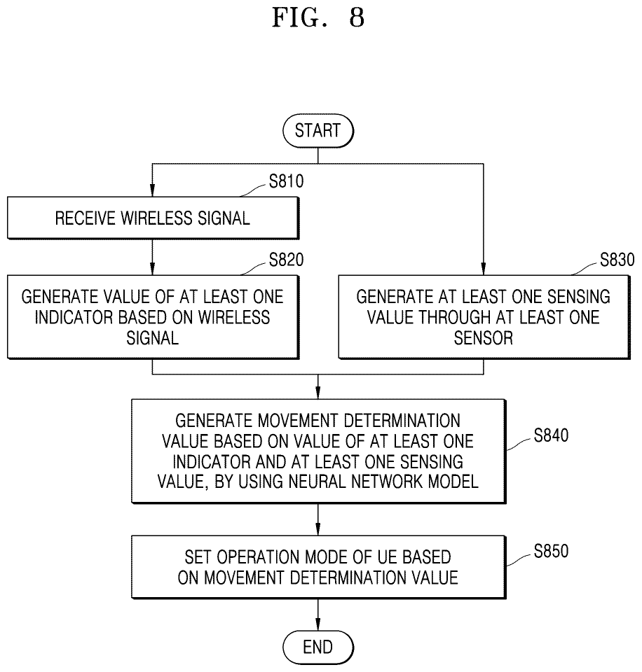

FIG. 8 is a flowchart illustrating another example method for operating a UE, according to an embodiment.

Referring to FIG. 8, in an embodiment, a UE, such as the UE 100 described above with respect to FIG. 2 or FIG. 5, generates a movement determination value based on a value of at least one indicator and at least one sensing value and generates an operation mode of the UE.

In operation S810, the UE may receive a wireless signal. Operation S810 of FIG. 8 may be the same as operation S610 of FIG. 6.

In operation S820, the UE may generate a value of at least one indicator based on the wireless signal. Operation S820 of FIG. 8 may be the same as operation S620 of FIG. 6.

In operation S830, the UE may generate at least one sensing value using at least one sensor. An application processor of the UE may generate the at least one sensing value used to determine whether the UE is moving using the at least one sensor. In this case, operation S830 may be performed in parallel with operations S810 and S820.

In operation S840, the UE may generate a movement determination value based on the value of the at least one indicator and the at least one sensing value.

In some embodiments, as in the embodiment of FIG. 2, when a neural network model is used by a neural processor, a communication processor may transmit the value of the at least one indicator and the at least one sensing value to the neural processor. Next, the neural processor may generate a movement determination value based on the value of the at least one indicator and the at least one sensing value by using the neural network model. Next, the neural processor may transmit the movement determination value to the communication processor.

In some embodiments, as in the embodiment of FIG. 5, when the neural network model is used by the communication processor, the communication processor may generate the movement determination value based on the value of the at least one indicator and the at least one sensing value by using the neural network model.

In operation S850, the UE may set an operation mode of the UE based on the movement determination value. Operation S850 may be the same as described above with reference to FIG. 7.

When the operating method of the UE according to an embodiment as described above is used, a movement determination value of the UE may be generated by using at least one sensing value along with a value of at least one indicator, and an operation mode of the UE may be set based on the movement determination value. Accordingly, power consumption of the UE may be reduced.

FIGS. 9A and 9B are flowcharts illustrating an operation according to an operation mode of a UE, according to an embodiment.

Referring to FIG. 9A, in operation S910, a UE, such as the UE 100 described above with respect to FIG. 2 or FIG. 5, may determine whether an operation mode is a first operation mode using a communication processor.

When the operation mode is the first operation mode, the operation proceeds to operation S920, and in operation S920, the UE may periodically perform a cell search operation. Because the first operation mode is an operation mode set when it is determined that the UE is moving, the UE may periodically perform a cell search operation to perform smooth communication.

In contrast, when the operation mode is not the first operation mode, the operation proceeds to operation S930, and in operation S930, the UE may maintain a preset cell. When the operation mode is not the first operation mode, the operation mode may be a second operation mode. Because the second operation mode is an operation mode set when it is determined that the UE does not move, the UE may perform smooth communication even when a cell search operation is not periodically performed, and thus, the UE may maintain a preset cell without performing a cell search operation.

Referring to FIG. 9B, in operation S910, the UE 100 may determine whether an operation mode is a first operation mode using the communication processor.

When the operation mode is the first operation mode, the operation proceeds to operation S940, and in operation S940, the UE may periodically perform a beam sweeping operation. Because the first operation mode is an operation mode set when it is determined that the UE is moving, the UE may periodically perform a beam sweeping operation to perform smooth communication.

In contrast, when the operation mode is not the first operation mode, the operation proceeds to operation S950, and in operation S950, the UE may maintain a preset beam. When the operation mode is not the first operation mode, the operation mode may be a second operation mode. Because the second operation mode is an operation mode set when it is determined that the UE does not move, the UE may perform smooth communication even when a beam sweeping operation is not periodically performed, and thus, the UE may maintain a preset beam without performing a beam sweeping operation.

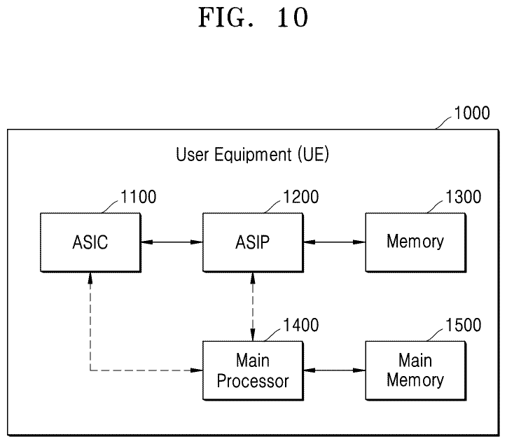

FIG. 10 is a block diagram illustrating a UE, according to an embodiment.

Referring to FIG. 10, a UE 1000 may include an application-specific integrated circuit (ASIC) 1100, an application-specific instruction set processor (ASIP) 1200, a memory 1300, a main processor 1400, and a main memory 1500. Two or more of the ASIC 1100, the ASIP 1200, and the main processor 1400 may communicate with each other. Also, at least two of the ASIC 1100, the ASIP 1200, the memory 1300, the main processor 1400, and the main memory 1500 may be embedded in one chip.

The ASIC 1100 is an integrated circuit customized for a specific purpose and may include, for example, an RFIC, a modulator, and a demodulator. The ASIP 1200 may support a dedicated instruction set for a specific application and may execute instructions included in the instruction set. The memory 1300 may communicate with the ASIP 1200 and may store a plurality of instructions executed by the ASIP 1200 as a non-transitory storage device. For example, the memory 1300 may include any type of memory accessible by the ASIP 1200, such as a random-access memory (RAM), a read-only memory (ROM), a tape, a magnetic disc, an optical disc, a volatile memory, a nonvolatile memory, or a combination thereof.

The main processor 1400 may control the UE 1000 by executing a plurality of instructions. For example, the main processor 1400 may control the ASIC 1100 and the ASIP 1200, and may process data received using a wireless communication network or process a user input to the UE 1000. The main memory 1500 may communicate with the main processor 1400 and may store a plurality of instructions executed by the main processor 1400 as a non-transitory storage. For example, the main memory 1500 may include any type of memory accessible by the main processor 1400 such as a RAM, a ROM, a tape, a magnetic disc, an optical disc, a volatile memory, a nonvolatile memory, or a combination thereof.

Elements of the UE 100 according to an embodiment described with reference to FIGS. 1 to 9 may correspond to or be included in at least one of elements included in the UE 1000 of FIG. 10. For example, operations of the UE 100 of FIG. 2 may be implemented as a plurality of instructions stored in the memory 1300, and the ASIP 1200 may perform an operation or at least one step of the UE 100 by executing the plurality of instructions stored in the memory 1300. In another example, an operation of the UE 100 of FIG. 2 may be implemented as a hardware block and may be included in the ASIC 1100. In another example, an operation of the UE 100 of FIG. 2 may be implemented as a plurality of instructions stored in the main memory 1500, and the main processor 1400 may perform an operation of the UE 100 by executing the plurality of instructions stored in the main memory 1500.

As described above, embodiments have been illustrated in the drawings and described in the specification. While embodiments have been described using specific terms, this is only used for the purpose of explaining the inventive concept and is not used to limit the meaning and scope of the present disclosure. Hence, it will be understood by one of ordinary skill in the art that various modifications and other equivalent embodiments may be made therefrom. Accordingly, the scope of the present disclosure should be defined by the following claims.

While the various embodiments has been described with reference to the drawings, it will be understood that various changes in form and details may be made therein without departing from the spirit and scope of the following claims.

What is claimed is:

1. A user equipment (UE) comprising:
a transceiver configured to receive a wireless signal;
a communication processor configured to generate a value of at least one indicator based on the wireless signal; and
a neural processor configured to receive the value of the at least one indicator from the communication processor, and generate a movement determination value by determining whether the UE is moving based on the value of the at least one indicator by using a neural network model,
wherein the communication processor is further configured to receive the movement determination value from the neural processor and set an operation mode of the UE based on the movement determination value.

2. The UE of claim 1, wherein the at least one indicator comprises at least one of: a global cell identifier (ID), a physical cell ID, a frequency band, a bandwidth, received signal received power (RSRP), reference signal received quality (RSRQ), a received signal strength indicator (RSSI), a signal to interference plus noise ratio (SINR), a number of resource blocks, a channel quality indicator (CQI), a rank indicator (RI), a precoding matrix indicator (PMI), a modulation and coding scheme (MCS), a modulation order, a block error rate (BLER), transmission power, a Doppler frequency, or a delay spread.

3. The UE of claim 1, further comprising an application processor configured to generate at least one sensing value using at least one sensor,
wherein the neural processor is further configured to:
receive the at least one sensing value from the application processor, and
generate the movement determination value based on the value of the at least one indicator and the at least one sensing value, by using the neural network model.

4. The UE of claim 3, wherein the neural processor is further configured to
generate a first determination value by determining whether the UE is moving, based on the value of the at least one indicator, by using a first neural network model,
generate a second determination value by determining whether the UE is moving, based on the at least one sensing value, by using a second neural network model, and
generate the movement determination value based on the first determination value and the second determination value, using a decision circuit.

5. The UE of claim 3, wherein the neural processor is further configured to:
generate a first determination value by determining whether the UE is moving based on the value of the at least one indicator, by using a first neural network model, and
generate the movement determination value by determining whether the UE is moving based on the first determination value and the at least one sensing value, by using a second neural network model.

6. The UE of claim 3, wherein the neural processor is further configured to:
generate a second determination value by determining whether the UE is moving based on the at least one sensing value, by using a second neural network model, and
generate the movement determination value by determining whether the UE is moving based on the second determination value and the value of the at least one indicator, by using a first neural network model.

7. The UE of claim 3, wherein the at least one sensor comprises at least one of: a gyro sensor, an acceleration sensor, a linear acceleration sensor, or a geomagnetic sensor.

8. The UE of claim 1, wherein the communication processor is further configured to:
when the movement determination value indicates that the UE is moving, set the operation mode of the UE to a first operation mode, and
when the movement determination value indicates that the UE does not move, set the operation mode of the UE to a second operation mode.

9. The UE of claim 8, wherein the communication processor is further configured to:
periodically perform a cell search operation, when the operation mode of the UE is the first operation mode, and
maintain a preset cell, when the operation mode of the UE is the second operation mode.

10. The UE of claim 8, wherein the communication processor is further configured to:
update a beam by periodically performing a beam sweeping operation, when the operation mode of the UE is the first operation mode, and
maintain a preset beam, when the operation mode of the UE is the second operation mode.

11. A user equipment (UE) comprising:
a transceiver configured to receive a wireless signal; and
a communication processor configured to generate a value of at least one indicator based on the wireless signal,
wherein the communication processor is further configured to:
generate a movement determination value by determining whether the UE is moving based on the value of the at least one indicator, by using a neural network model, and
set an operation mode of the UE based on the movement determination value.

12. The UE of claim 11, further comprising an application processor configured to generate at least one sensing value using at least one sensor,
wherein the communication processor is further configured to:
receive the at least one sensing value from the application processor, and
generate the movement determination value based on the value of the at least one indicator and the at least one sensing value, by using the neural network model.

13. The UE of claim 12, further comprising a buffer configured to receive and store the at least one sensing value from the application processor,
wherein the communication processor is further configured to receive the at least one sensing value from the buffer.

14. The UE of claim 12, wherein the communication processor is further configured to:
generate a first determination value by determining whether the UE is moving based on the value of the at least one indicator, by using a first neural network model,
generate a second determination value by determining whether the UE is moving based on the at least one sensing value, by using a second neural network model, and
generate the movement determination value based on the first determination value and the second determination value.

15. The UE of claim 12, wherein the communication processor is further configured to:
generate a first determination value by determining whether the UE is moving based on the value of the at least one indicator, by using a first neural network model, and
generate the movement determination value by determining whether the UE is moving based on the first determination value and the at least one sensing value, by using a second neural network model.

16. The UE of claim 12, wherein the communication processor is further configured to:
generate a second determination value by determining whether the UE is moving based on the at least one sensing value, by using a second neural network model, and
generate the movement determination value by determining whether the UE is moving based on the second determination value and the value of the at least one indicator, by using a first neural network model.

17. The UE of claim 11, wherein the communication processor is further configured to:
set the operation mode of the UE to a first operation mode, when the movement determination value indicates that the UE is moving, and
set the operation mode of the UE to a second operation mode, when the movement determination value indicates that the UE does not move.

18. The UE of claim 17, wherein the communication processor is further configured to:
periodically perform a cell search operation, when the operation mode of the UE is the first operation mode, and
maintain a preset cell, when the operation mode of the UE is the second operation mode.

19. The UE of claim 17, wherein the communication processor is further configured to:
update a beam by periodically performing a beam sweeping operation, when the operation mode of the UE is the first operation mode, and
maintain a preset beam, when the operation mode of the UE is the second operation mode.

20. A user equipment (UE) comprising:
a transceiver configured to receive a wireless signal;
a communication processor configured to generate a value of at least one indicator based on the wireless signal;
an application processor configured to generate at least one sensing value using at least one sensor; and
a neural processor configured to receive the value of the at least one indicator from the communication processor, receive the at least one sensing value from the application processor, and generate a movement determination value by determining whether the UE is moving based on the value of the at least one indicator and the at least one sensing value.
